(19) United States
(12) Patent Application Publication
(10) Pub. No.: US 2013/0032910 A1
(43) Pub. Date: Feb. 7, 2013

(54) MAGNETIC MEMORY DEVICE AND METHOD OF MANUFACTURING THE SAME

(71) Applicants: Dong Ha Jung, Ichon-si (KR); Ki Seon Park, Ichon-si (KR); Guk Cheon Kim, Ichon-si (KR)

(72) Inventors: Dong Ha Jung, Ichon-si (KR); Ki Seon Park, Ichon-si (KR); Guk Cheon Kim, Ichon-si (KR)

(21) Appl. No.: 13/251,461

(22) Filed: Oct. 3, 2011

(30) Foreign Application Priority Data
Aug. 5, 2011 (KR) 10-2011-0078269

(51) Int. Cl. H01L 29/82; H01L 21/8246

(52) U.S. Cl. 257/421; 438/3; 257/E29.323; 257/E21.665

(57) ABSTRACT

A magnetic memory device includes a first fixing layer, a first tunnel barrier coupled to the first fixing layer, a free layer coupled to the first tunnel barrier and having a stacked structure including a first ferromagnetic layer, an oxide tunnel spacer, and a second ferromagnetic layer, a second tunnel barrier coupled to the free layer, and a second fixing layer coupled to the second tunnel barrier.

### CROSS-REFERENCES TO RELATED APPLICATION

The present application claims priority under 35 U.S.C. 119(a) to Korean application number 10-2011-0078269, filed on Aug. 5, 2011, in the Korean Patent Office, which is incorporated by reference in its entirety as if set forth herein in full.

### BACKGROUND

1. Technical Field

Exemplary embodiments of the present invention relate to a semiconductor memory device, and more particularly, to a magnetic memory device and a method of manufacturing the same.

2. Related Art

Magnetic memory devices store information using a magnetic field and exhibit low power consumption, endurance and fast operation speed. Further, the magnetic memory devices are nonvolatile devices where they retain data even after power off and are considered to be next generation memory devices.

Exemplary magnetic memory devices are magnetoresistance random access memory (MRAM) devices for producing Giga-bit-sized nonvolatile memories, where they use tunnel magnetoresistance (TMR) effect.

Here, the TMR effect occurs in structures including a pair of ferromagnetic layers and a tunnel insulating layer located therebetween. Since there is little exchange coupling between the ferromagnetic layers, larger magnetoresistance may be obtained even with a low magnetic field. A TMR device has a superior magnetoresistance characteristic and a relatively low switching current in storing information as compared with a giant magnetoresistance (GMR) device.

Since a switching current characteristic of a magnetic memory device is a parameter that determines a total amount of current consumption, reduction in switching current is useful in increasing the integration density of the magnetic memory device. Even though the switching current of a TMR device is reduced by increasing a thickness of the tunnel insulating layer, the magnetoresistance also decreases when the thickness of the tunnel insulating layer increases. On the other hand, when the thickness of the tunnel insulating layer is reduced to increase the magnetoresistance, reliability and endurance of products deteriorate and program current increases.

A method to address such features is desired, where, for example, the composition and volume of a free layer may be optimized to reduce the switching current. Here, by reducing the volume of the free layer, the switching current may be reduced, but the TMR effect and thermal stability may deteriorate.

### SUMMARY

According to one aspect of an exemplary embodiment, a magnetic memory device includes a first fixing layer, a first tunnel barrier coupled to the first fixing layer, a free layer coupled to the first tunnel barrier and having a stacked structure including a first ferromagnetic layer, an oxide tunnel spacer, a second ferromagnetic layer, a second tunnel barrier coupled to the free layer, and a second fixing layer coupled to the second tunnel barrier.

According to another aspect of an exemplary embodiment, a magnetic memory device includes a first fixing layer, a first tunnel barrier coupled to the first fixing layer and including magnesium oxide to (MgO), a free layer coupled to the first tunnel barrier and having a stacking structure including a first ferromagnetic layer, an oxide tunnel spacer, a second ferromagnetic layer, a second tunnel barrier coupled to the free layer and including MgO, and a second fixing layer coupled to the second tunnel barrier.

According to still another aspect of an exemplary embodiment, a method of manufacturing a magnetic memory device is provided. The method includes forming a seed layer on a semiconductor substrate having a lower conductive layer formed thereon, forming a first fixing layer on a seed layer, forming a first tunnel barrier on the first fixing layer, forming a free layer by stacking a first ferromagnetic layer, an oxide tunnel spacer, wherein the free layer includes the first ferromagnetic layer, the oxide tunnel spacer, and the second ferromagnetic layer, and a second ferromagnetic layer on the first tunnel barrier, forming a second tunnel barrier on the free layer, forming a second fixing layer on the second tunnel barrier, and forming a capping layer on the second fixing layer.

These and other features, aspects, and embodiments are described below in the section entitled “DESCRIPTION OF EXEMPLARY EMBODIMENT.”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a view illustrating a configuration of a magnetic memory device according to a first exemplary embodiment;

FIG. 2 is a view illustrating a configuration of a magnetic memory device according to a second exemplary embodiment;

FIG. 3 is a view illustrating a configuration of a magnetic memory device according to a third exemplary embodiment;

FIG. 4 is a view illustrating a configuration of a magnetic memory device according to a fourth exemplary embodiment;

FIG. 5 is a view illustrating a coupling characteristic between free layers in the magnetic memory device of FIG. 4; and

FIG. 6 is a view illustrating a configuration of a magnetic memory device according to a fifth exemplary embodiment.

### DESCRIPTION OF EXEMPLARY EMBODIMENT

Exemplary embodiments are described herein with reference to cross-sectional views of exemplary embodiments (and intermediate structures). However, proportions and shapes illustrated in the drawings are exemplary only and may vary depending on various manufacturing techniques and/or design considerations. In parts of the drawings, lengths and sizes of layers and regions of exemplary embodiments may be exaggerated for clarity in illustration. Throughout the drawings, like reference numerals denote like elements. Throughout the disclosure, when a layer is referred to as being “on” another layer or substrate, it can be directly on the other layer or substrate, or intervening layers may also be present.

Hereinafter, exemplary embodiments of the present invention are described with reference to the accompanying drawings.

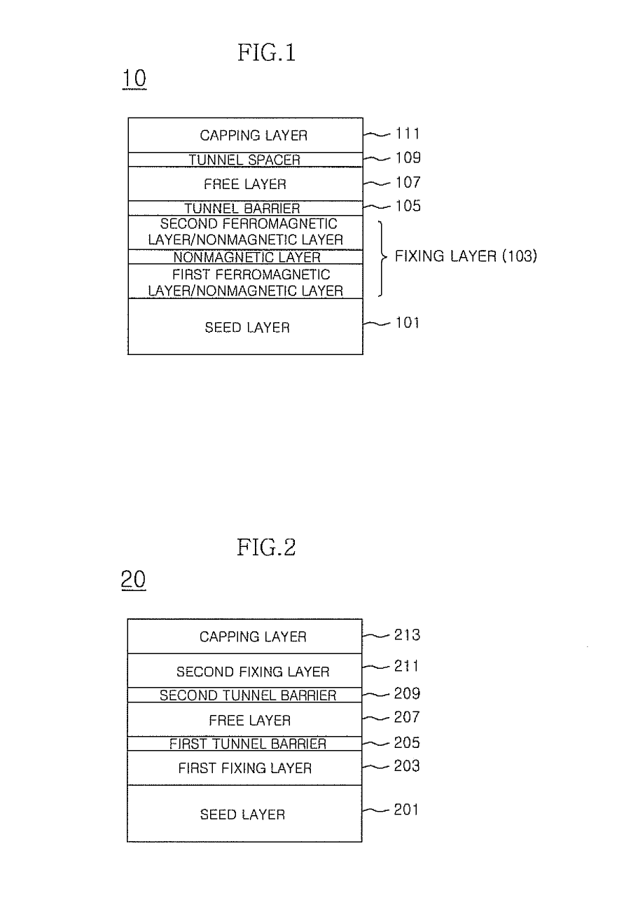

FIG. 1 is a configuration diagram of a magnetic memory device according to a first exemplary embodiment.

Referring to FIG. 1, the magnetic memory device 10 includes a seed layer 101, a fixing layer 103, a tunnel barrier 105, a free layer 107, a tunnel spacer 109, and a capping layer 111 sequentially formed on a semiconductor substrate (not shown) on which a lower conductive layer (not shown) is formed.

For example, the fixing layer 103 may be formed by sequentially stacking a first ferromagnetic layer, a non-magnetic layer, and a second ferromagnetic layer. According to an example, the first and second ferromagnetic layers may be formed of a compound material including cobalt iron (CoFe) and the non-magnetic layer may be formed of a metal material having no magnetism, for example, ruthenium (Ru).

The tunnel barrier 105 may be formed using magnesium oxide

(MgO). When the tunnel barrier 105 is formed using MgO, tunnel magnetoresistance (TMR) may increase by about a factor of 10 at room temperature.

The tunnel spacer 109 formed on the free layer 107 may also be formed using MgO. When the tunnel spacer 109 is formed using MgO, a partial perpendicular magnetic anisotropy (PMA) effect can be induced in the free layer 107, and thus, low switching current may be obtained.

FIG. 2 is a configuration diagram of a magnetic memory device according to a second exemplary embodiment.

Referring to FIG. 2, the magnetic memory device 20 includes a seed layer 201, a first fixing layer 203, a first tunnel barrier 205, a free layer 207, a second tunnel barrier 209, a second fixing layer 211, and a capping layer 213 sequentially formed on a semiconductor substrate (not shown) having a lower conductive layer (not shown) formed thereon.

The first fixing layer 203, a free layer 207, and the second fixing layer 211 may be formed using a compound material including CoFe such as CoFeB. The first and second tunnel barriers 205 and 209 may be formed using MgO.

In the magnetic memory device 20 according to the second exemplary embodiment, dual tunnel barriers 205 and 209 are formed using MgO with respect to the free layer 207 so that an effective spin transfer characteristic is increased, and thus, low switching current is obtained.

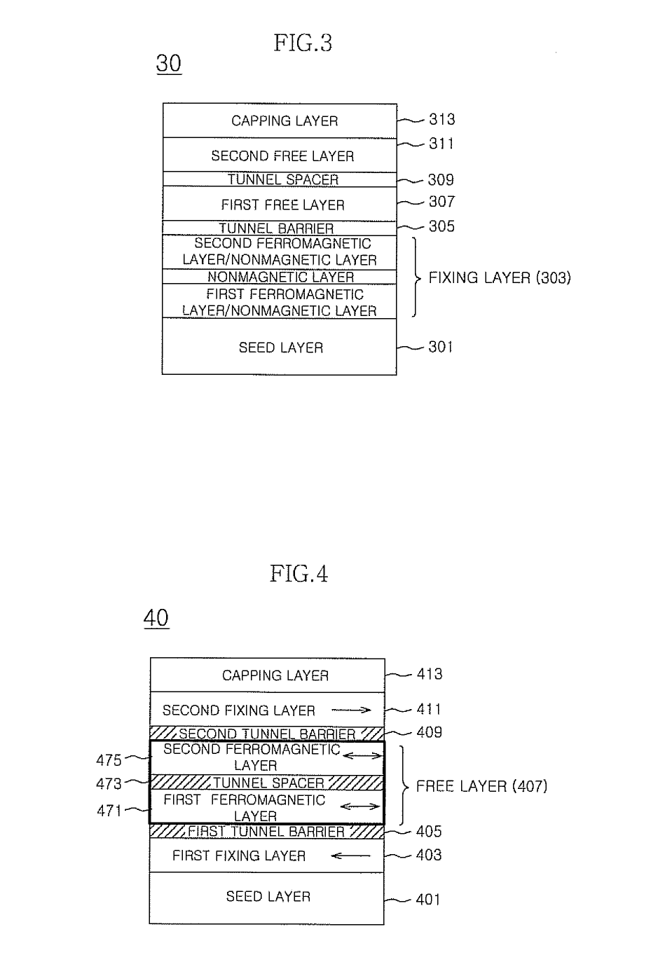

FIG. 3 is a configuration diagram of a magnetic memory device according to a third exemplary embodiment.

Referring to FIG. 3, the magnetic memory device 30 includes a seed layer 301, a fixing layer 303, a tunnel barrier 305, a first free layer 307, a tunnel spacer 309, a second free layer 311, and a capping layer 313 sequentially formed on a semiconductor substrate (not shown) with a lower conductive layer (not shown) formed thereon.

For example, the fixing layer 303 may be formed by sequentially stacking a first ferromagnetic layer, a non-magnetic layer, and a second ferromagnetic layer. In particular, the first and second ferromagnetic layers may be formed of a compound material including CoFe as a constituent and the non-magnetic layer may be formed of a non-magnetic metal material such as Ru.

The first and second free layers 307 and 311 may be formed using a compound material including CoFe such as CoFeB and the tunnel spacer 309 may be formed between the first and second free layers 307 and 311 using a non-magnetic material such as Ru.

The tunnel barrier 305 may be formed using MgO.

According to an example, the first and second free layers 307 and 311 are coupled by the tunnel spacer 309 formed of Ru and thus appropriate thermal stability may be obtained.

FIG. 4 is a configuration diagram of a magnetic memory device 40 according a fourth exemplary embodiment.

Referring to FIG. 4, the magnetic memory device 40 according to the fourth exemplary embodiment includes a seed layer 401, a first fixing layer 403, a first tunnel barrier 405, a free layer 407, a second tunnel barrier 409, a second fixing layer 411, and a capping layer 413 sequentially formed.

In the fourth exemplary embodiment, the seed layer 401 and the capping layer 413 may be formed using tantalum (Ta), Ru, platinum manganese (PtMn), chromium (Cr), tungsten (W), titanium (Ti), tantalum nitride (TaN). Alternatively, the seed layer 401 and the capping layer 413 may be formed of a combination of the above-metal material, for example, Ta/Ru.

The first fixing layer 403 and the second fixing layer 411 may be formed with a compound material including CoFe selected from the group including CoFe, CoFeB, CoFeBTa, and CoFeBSi. The first and second fixing layers 403 and 411 may be formed by stacking an antiferromagetic alloy and a compound material including CoFe selected from the group including PtMn/CoFe, PtMn/CoFeB, PtMn/CoFeBTa, or PtMn/CoFeBSi. Further, the first and second fixing layers 403 and 411 may be formed using an alloy including Fe (for example, FePt, FePtB, FePd, or FePdB) or using an alloy including Co (for example, CoPt, CoPtB, CoPd, or CoPdB).

A first ferromagnetic layer 471 and a second ferromagnetic layer 475 constituting the free layer 407 may be formed using a compound material including CoFe selected from the group including CoFe, CoFeB, CoFeBTa, or CoFeBSi.

A tunnel spacer 473 of the free layer 407 is coupled between the first and second ferromagnetic layers 471 and 475 and may be an oxide spacer such as MgO. The tunnel spacer 473 may be formed using metal oxide such as aluminum oxide (Al₂O₃), titanium oxide (TiO₂), hafnium oxide (HfO₂) or tantalum oxide (Ta₂O₃). Further, the tunnel spacer 473 may be deposited by using a radio frequency (RF) sputtering method or a pulsed direct current (DC) sputtering method. When metal oxide is used for the tunnel spacer 473, the tunnel spacer 473 may be formed by depositing and oxidizing a metal material.

The first tunnel barrier 405 and the second tunnel barrier 409 may be formed using MgO. When MgO serves as the tunnel barrier (405 and 409) of the magnetic memory device, the MgO is a material capable of increasing TMR by about a factor of 10 at room temperature. In the fourth exemplary embodiment, the first tunnel barrier 405 is formed between the first fixing layer 403 and the free layer 407 and the second tunnel barrier 409 is formed between the free layer 407 and the second fixing layer 411, thereby forming dual tunnel barriers. Thereby, a dual MTJ structure is substantially formed and thus the TMR effect can be maximized.

Further, by a partial PMA effect generated by a junction between oxide and a ferromagnetic layer at a surface boundary between the first tunnel barrier 405 and the free layer 407 and a surface boundary between the second tunnel barrier 409 and the free layer 407, switching current may be minimized/reduced.

Here, even though the two ferromagnetic layers 471 and 475 constituting the free layer 407 are formed to be thin in thicknesses, the MgO tunnel spacer 473 are coupled between the two ferromagnetic layers 471 and 475 so that the free layer 407 has a sufficient overall volume. Further, the partial PMA is obtained by the MgO tunnel spacer 473 between the first and second ferromagnetic layers 471 and 475. Therefore, the MgO tunnel spacer 473 causes the two ferromagnetic layers 471 and 475 to be ferromagnetically coupled or to be antiferromagnetically coupled, where the sufficient overall volume of the free layer 207 is obtained to maximize thermal stability and at the same time, the partial PMA effect is generated in surface boundaries between the two ferromagnetic layers 471 and 475 and the tunnel spacer 473 to reduce the switching current.

FIG. 5 is a view illustrating a coupling characteristic between free layers in the magnetic memory device of FIG. 4.

FIG. 5 illustrates a coupling characteristic of a contact surface in the case where MgO is introduced between two ferromagnetic layers.

In the case of a ferromagnetic coupling characteristic (A), it is seen that an exchange coupling energy (J(erg/cm²)) is maximum when MgO serving as a tunnel spacer has a thickness of 0.9 nm. In the case of an antiferromagnetic coupling characteristic (B), it is seen that an exchange coupling energy (J(erg/cm²)) is maximum when an MgO tunnel spacer has a thickness of 0.6 to 0.7 nm.

That is, when the MgO tunnel spacer is interposed between the ferromagnetic layers, all ferromagnetic and antiferromagnetic coupling characteristics are superior and the two ferromagnetic layers are coupled in a magnetic/ferromagnetic state, and thus, when the MgO tunnel spacer is applied to the free layer, a sufficient volume of the free layer may be obtained and the respective thicknesses of the ferromagnetic layers may be reduced/minimized.

While the horizontal magnetic memory device as described above has been illustrated, the exemplary embodiments of the present invention are not limited thereto and the exemplary magnetic memory devices according to the present invention may be applied to the perpendicular magnetic memory device.

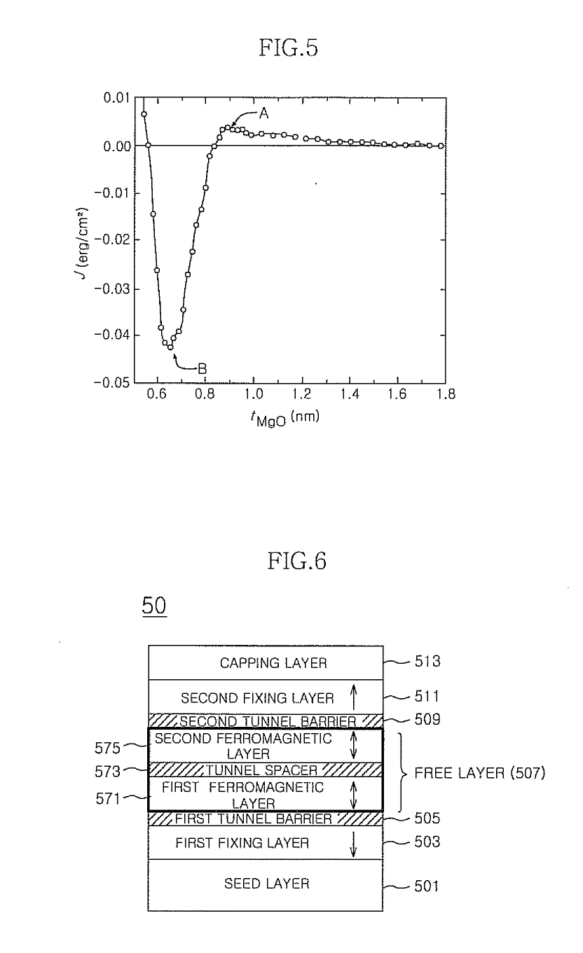

FIG. 6 is a configuration of a magnetic memory device according to a fifth exemplary embodiment.

The magnetic memory device 50 according to the fifth exemplary embodiment includes a seed layer 501, a first fixing layer 503, a first tunnel barrier 505, a free layer 507, a second tunnel barrier 509, a second fixing layer 511, and a capping layer 513 sequentially formed.

Materials constituting respective layers are similar to those of the magnetic memory device 40 as shown in FIG. 4. According to an example, the first and second fixing layers 503 and 511 and first and second ferromagnetic layers 571 and 575 may be formed using CoFeB and the first and second tunnel barrier 505 and 509 and a tunnel spacer 573 may be formed using MgO.

Since the MgO tunnel spacer 573 is coupled between the first and second ferromagnetic layers 571 and 575, the first and second ferromagnetic layers 571 and 575 may be formed to be thin (for example, 2.2 nm or less) and appropriate characteristics of the horizontal magnetic memory device are obtained.

Here, the free layer 507 is capable of being antiferromagnetically coupled and ferromagnetically coupled.

The magnetic memory device according to the inventive concept has a superior TMR characteristic. Further, switching current may be minimized/reduced and at the same time, thermal stability may be maximized so that miniaturization of a memory device may be achieved.

According to the exemplary embodiments, a tunnel barrier using oxide is formed between a first fixing layer and a free layer and between the free layer and a second fixing layer to maximize a TMR effect and to induce a partial PMA in a surface boundary between the oxide and the ferromagnetic material, thereby minimizing switching current.

While, when the switching current is minimized/reduced, a volume of a free layer and thermal stability tends to decrease, according to exemplary embodiments of the present invention, a free layer is formed of a first ferromagnetic layer, a tunnel spacer, and a second ferromagnetic layer and the tunnel spacer using oxide causes the first and second ferromagnetic layers to be ferromagnetically coupled or to be antiferromagnetically coupled. Therefore, although the first and second ferromagnetic layers constituting the free layer are formed to be thin, the switching current may be reduced and a sufficient volume for the free layer is obtained to maximize thermal stability.

While certain embodiments have been described above, it will be understood that the embodiments described are by way of example only. Accordingly, the present invention should not be limited to the specific disclosed embodiments, and claims should be broadly interpreted to include all reasonably suitable embodiments consistent with the exemplary embodiments.

What is claimed is:

1. A magnetic memory device, comprising:
a first fixing layer;
a first tunnel barrier coupled to the first fixing layer;
a free layer coupled to the first tunnel barrier and having a stacked structure including a first ferromagnetic layer, an oxide tunnel spacer, a second ferromagnetic layer;
a second tunnel barrier coupled to the free layer; and
a second fixing layer coupled to the second tunnel barrier.

2. The magnetic memory device of claim 1, wherein the oxide tunnel spacer includes magnesium oxide (MgO).

3. The magnetic memory device of claim 1, wherein the oxide tunnel spacer includes any one selected from the group consisting of aluminum oxide (Al₂O₃), titanium oxide (TiO₂), hafnium oxide (HfO₂), and tantalum oxide (Ta₂O₃).

4. The magnetic memory device of claim 1, wherein each of the first and second tunnel barriers includes MgO.

5. The magnetic memory device of claim 1, wherein each of the first fixing layer and the second fixing layer includes a compound material including cobalt iron (CoFe) as a constituent.

6. The magnetic memory device of claim 1, wherein each of the first fixing layer and the second fixing layer has a stacking structure of an antiferromagnetic alloy and a compound material including CoFe as a constituent.

7. The magnetic memory device of claim 1, wherein each of the fixing layer and the second fixing layer includes an alloy including Fe.

8. The magnetic memory device of claim 1, wherein each of the first fixing layer and the second fixing layer includes an alloy including Co.

9. The magnetic memory device of claim 1, wherein each of the first ferromagnetic layer and the second ferromagnetic layer includes a material selected from the group including CoFe.

10. A magnetic memory device, comprising:
a first fixing layer;
a first tunnel barrier coupled to the first fixing layer and including magnesium oxide (MgO);
a free layer coupled to the first tunnel barrier and having a stacking structure including a first ferromagnetic layer, an oxide tunnel spacer, and a second ferromagnetic layer;
a second tunnel barrier coupled to the free layer and including MgO; and
a second fixing layer coupled to the second tunnel barrier.

11. The magnetic memory device of claim 10, wherein the oxide tunnel spacer includes magnesium oxide (MgO).

12. The magnetic memory device of claim 10, wherein each of the first fixing layer and the second fixing layer includes a compound material including cobalt iron (CoFe) as a constituent.

13. The magnetic memory device of claim 10, wherein each of the first ferromagnetic layer and the second ferromagnetic layer includes a compound material including CoFe as a constituent.

14. A method of manufacturing a magnetic memory device, comprising:
forming a seed layer on a semiconductor substrate having a lower conductive layer formed thereon;
forming a first fixing layer on a seed layer;
forming a first tunnel barrier on the first fixing layer;
forming a free layer by stacking a first ferromagnetic layer, an oxide tunnel spacer, and a second ferromagnetic layer on the first tunnel barrier, wherein the free layer includes the first ferromagnetic layer, the oxide tunnel spacer, and the second ferromagnetic layer;
forming a second tunnel barrier on the free layer;
forming a second fixing layer on the second tunnel barrier; and
forming a capping layer on the second fixing layer.

15. The method of claim 14, wherein the oxide tunnel spacer includes magnesium oxide (MgO).

16. The method of claim 14, wherein the oxide tunnel spacer includes any one selected from the group consisting of aluminum oxide (Al₂O₃), titanium oxide (TiO₂), hafnium oxide (HfO₂), and tantalum oxide (Ta₂O₃).

17. The method of claim 14, wherein each of the first and second tunnel barriers includes MgO.

18. The method of claim 14, wherein each of the first fixing layer and the second fixing layer includes a compound material including cobalt iron (CoFe) as a constituent.

19. The method of claim 14, wherein each of the first ferromagnetic layer and the second ferromagnetic layer includes a compound material including CoFe as a constituent.
